(19) United States
(12) Patent Application Publication
(10) Pub. No.: US 2001/0001507 A1
(43) Pub. Date: May 24, 2001

(54) SUBSTRATE FOR A SEMICONDUCTOR DEVICE, A SEMICONDUCTOR DEVICE, A CARD TYPE MODULE, AND A DATA MEMORY DEVICE

(75) Inventors: MASATOSHI FUKUDA, YOKOHAMA-SHI (JP); JUN OHMORI, YOKOHAMA-SHI (JP)

Correspondence Address: FINNEGAN HENDERSON FARABOW, GARRETT & DUNNER, 1300 I STREET NW, WASHINGTON, DC, 200053315

(73) Assignee: Kabushiki Kaishi Toshiba

(21) Appl. No.: 08/863,556

(22) Filed: May 27, 1997

(30) Foreign Application Priority Data
May 27, 1996 (JP) 8-131825

(51) Int. Cl. H01L 23/48; H01L 23/52; H01L 29/40

(52) U.S. Cl. 257/778

(57) ABSTRACT

In the substrate for a semiconductor device of the present invention, a second substrate having an opening portion is adhered on a first flat substrate. The opening portion makes the surface of the first substrate exposed and contains a semiconductor chip. Chip connection terminals to be connected to the semiconductor chip are provided on the second substrate. External connection terminals are provided on the back surface of the first substrate. The chip connection terminals and the external connection terminals are connected with each other by a wiring pattern passing through through-holes formed and penetrating both the first and second substrate.

### BACKGROUND OF THE INVENTION

The present invention relates to a substrate for a semiconductor device, comprising a flat external connection terminal used for IC cards or the like and having a surface molded with resin, a semiconductor device using the substrate, a card type module using the substrate, and a data memory device using the substrate.

In recent years, as an electric devices have become smaller and thinner in size and thickness, reductions in thickness of semiconductor devices have been required. In the field of IC cards, this requirement is particularly strong.

FIG. 1 shows a semiconductor device used in IC cards or the like. In this semiconductor device, a concave portion 25 is provided in a substrate 21 having a thickness of 0.2 to 0.3 mm, for example.

A semiconductor chip 26 is fixed to the concave portion 25 of the substrate 21 by means of adhesion material 27. A bonding pad (not shown) on the semiconductor chip 26 and a chip connection terminal 23 on the substrate are connected with each other by a gold wire 28 or the like.

Further, the semiconductor chip 26 is enclosed with resin 29. The resin enclosure is provided on only the surface of the substrate 21 where the semiconductor chip 26 is provided. The chip connection terminal 23 is connected to a flat external connection terminal 22 provided on the other surface of the substrate where the semiconductor chip 26 is not provided, via a wiring pattern passing through a through hole 24.

The concave portion 25 of the substrate 21 is formed, for example, such that a distance of 0.13 mm is maintained between the exposed surface of the external terminal 22 and the bottom surface of the concave portion 25. This distance is called hereinafter a design value of a concave portion.

The semiconductor chip 26 uses at least a non-volatile memory. For example, a flash type memory of a NAND flash is used as the non-volatile memory.

FIG. 2 shows a structure of the substrate having a concave portion which is used in a semiconductor device as described above. In the following explanation, the same elements in this figure as those in FIG. 1 will be referred to by the same reference symbols, and explanation of those elements will be omitted. In this substrate structure, copper wiring patterns are formed on both surfaces of a flat substrate 21 made of resin. After the wiring patterns are plated, a part of the substrate 21 is cut out by cutting process to form a concave portion 25.

However, when a concave portion 25 is formed in the substrate 21 by cutting process, the following problem occurs. Cutting process is normally carried out with use of a routing process machine. A routing process machine is placed, adsorbed on a process table, and a metal rotation mill is rotated at a high speed, which is brought into contact with an object to be processed, thereby to grind the object.

In this cutting process, the metal rotation mill is moved so as to draw a spiral trace from the center of the substrate 21 to the outside, with the metal rotation mill kept rotated, and thus, the mill bores out a concave in the substrate 21. This process method causes errors in positional precision of the routing process machine, so that there is a possibility that substrates cannot be processed as designed.

In addition, in case where the area of a substrate which should be subjected to cutting process is large, a long processing time is required. Therefore, the manufacturing yield of substrates is low resulting in high manufacturing costs.

Even if the cutting process is carried out just as designed, the number of times for which the metal rotation mill passes differs between positions, so that convex and concave portions are formed on the surface to be processed. If the substrate 21 is set on a processing table by incomplete adsorption, the substrate 21 is placed obliquely so that the surface to be processed may be inclined.

In addition, the top end of a routing process tool is worn away gradually, the surfaces processed by cutting become rougher as the processing period is elapsed. Normally, a semiconductor chip 26 is adhered on a substrate 21 by providing a plurality of drops of adhesion resin in a grid-like arrangement on an adhering surface, e.g., on a rough concave surface as described above. However, in an adhesion is thus dropped on such rough concave surface to adhere a semiconductor chip on a substrate 21, the resin adhesion does not sufficiently spreads over the surface, but is solidified in form of drops or causes a cavity between the semiconductor chip 26 and the substrate 21.

As a result of this, when the adhering surface is viewed from the surface of an external connection terminal, unevenness of the resin adhesion caused by insufficient spread is observed even with eyes since the substrate 21 is thin at the concave portion 25. Thus, the outlook of the semiconductor device is degraded. In addition, air remaining on the adhering surface expands after molding and the semiconductor 26 is peeled off from the substrate, in several cases.

### BRIEF SUMMARY OF THE INVENTION

The present invention has been made in view of the above situation, and has an object of providing a substrate for a semiconductor device, a semiconductor device, a card type module, and a data memory device, which achieve low manufacturing costs and high reliability.

In order to achieve the above object, a substrate for a semiconductor device according to the present invention comprises:

a flat first substrate;

a second substrate adhered on a surface of the first substrate and having an opening from which the surface of the first substrate is exposed and which contains a semiconductor chip;

a chip connection terminal provided on the second substrate and connected to the semiconductor chip;

an external connection terminal provided on a back surface of the first substrate;

a through-hole provided so as to penetrate the first and second substrates; and

a wiring pattern extending through the through-hole thereby connecting the chip connection terminal to the external terminal.

Further, according to the present invention, there is provided a substrate for a semiconductor device comprising:

a flat first substrate;

a chip connection terminal provided on a surface of the first substrate and connected to a semiconductor chip;

an external connection terminal provided on a back surface of the first substrate;

a through-hole provided so as to penetrate the first substrate;

a wiring pattern extending through the through-hole thereby connecting the chip connection terminal to the external terminal; and

a second substrate adhered on the surface of the first substrate and having an opening from which the surface of the first substrate and the chip connection terminal are exposed and which contains the semiconductor chip.

In addition, according to the present invention, there is provided a semiconductor device comprising:

a flat first substrate;

a semiconductor chip provided on the first substrate;

a second substrate adhered on a surface of the first substrate and having an opening from which the surface of the first substrate is exposed and which contains the semiconductor chip;

a chip connection terminal provided on the second substrate and connected to the semiconductor chip;

an external connection terminal provided on a back surface of the first substrate;

a through-hole provided so as to penetrate the first and second substrates;

a wiring pattern extending through the through-hole thereby connecting the chip connection terminal to the external terminal; and

resin for sealing the semiconductor chip on the first and second substrates.

According to the present invention, there is provided a semiconductor device:

a flat first substrate;

a semiconductor chip provided on the first substrate;

a chip connection terminal provided on a surface of the first substrate and connected to the semiconductor chip;

an external connection terminal provided on a back surface of the first substrate;

a through-hole provided so as to penetrate the first substrate;

a wiring pattern extending through the through-hole thereby connecting the chip connection terminal to the external terminal;

a second substrate adhered on the surface of the first substrate and having an opening from which the surface of the first substrate and the chip connection terminal are exposed and which contains the semiconductor chip; and

resin for sealing the semiconductor chip on the first and second substrates.

Further, according to the present invention, there is provided a card type module comprising

a base card having a concave portion, and

a semiconductor device provided in the concave portion, the semiconductor device including:

a flat first substrate;

a semiconductor chip provided on the first substrate;

a second substrate adhered on a surface of the first substrate and having an opening from which the surface of the first substrate is exposed and which contains the semiconductor chip;

a chip connection terminal provided on the second substrate and connected to the semiconductor chip;

an external connection terminal provided on a back surface of the first substrate;

a through-hole provided so as to penetrate the first and second substrates;

a wiring pattern extending through the through-hole thereby connecting the chip connection terminal to the external terminal; and

resin for sealing the semiconductor chip on the first and second substrates.

Further, according to the present invention, there is provided a card type module comprising

a base card having a concave portion, and

a semiconductor device provided in the concave portion of the base card, the semiconductor device including:

a flat first substrate;

a semiconductor chip provided on the first substrate;

a chip connection terminal provided on a surface of the first substrate and connected to the semiconductor chip;

an external connection terminal provided on a back surface of the first substrate;

a through-hole provided so as to penetrate the first substrate;

a wiring pattern extending through the through-hole thereby connecting the chip connection terminal to the external terminal;

a second substrate adhered on the surface of the first substrate and having an opening from which the surface of the first substrate and the chip connection terminal are exposed and which contains the semiconductor chip; and

resin for sealing the semiconductor chip on the first and second substrates.

Further, according to the present invention, there is provided a data memory device comprising

a card type module including a base card having a concave portion and a semiconductor device provided in the concave portion,

connector means consisting of a first connector connected to an external terminal of the card type module and a second connector connected to devices, and

an interface control circuit connected to the first and second connector, the semiconductor device including:

a flat first substrate;

a semiconductor chip provided on the first substrate;

a second substrate adhered on a surface of the first substrate and having an opening from which the surface of the first substrate is exposed and which contains the semiconductor chip;

a chip connection terminal provided on the second substrate and connected to the semiconductor chip;

an external connection terminal provided on a back surface of the first substrate;

a through-hole provided so as to penetrate the first and second substrates;

a wiring pattern extending through the through-hole thereby connecting the chip connection terminal to the external terminal; and

resin for sealing the semiconductor chip on the first and second substrates.

Further, according to the present invention, a data memory device comprising

a card type module including a base card having a concave portion and a semiconductor device provided in the concave portion of the base card,

connector means consisting of a first connector connected to an external connection terminal of the card type module and a second connector connected to devices, and

an interface control circuit connected to the first and second connectors, the semiconductor device including:

a flat first substrate;

a semiconductor chip provided on the first substrate;

a chip connection terminal provided on a surface of the first substrate and connected to the semiconductor chip,

an external connection terminal provided on a back surface of the first substrate;

a through-hole provided so as to penetrate the first substrate;

a wiring pattern extending through the through-hole thereby connecting the chip connection terminal to the external terminal;

a second substrate adhered on the surface of the first substrate and having an opening from which the surface of the first substrate and the chip connection terminal are exposed and which contains the semiconductor chip; and

resin for sealing the semiconductor chip on the first and second substrates.

In the substrate for a semiconductor device, the semiconductor device, the card type module, and the data memory device according to the present invention, which has the structure as described above, substrates are prepared by adhering together a substrate having an opening and a normal substrate, and therefore, a concave portion can be provided without cutting processing. Therefore, losses of substrates due to failures of cutting processing and increases in processing time due to an increase in the area of to be cut are prevented, so that a substrate of a low price can be manufactured with high manufacturing yield and low manufacturing costs.

In addition, the surface of the substrate not subjected to processing is exposed at the concave portion of the substrate, so that unevenness and inclinations are not caused and the surface roughness is maintained to be constant. Therefore, it is possible to securely bond a semiconductor chip, so that the wetness and tightness between the semiconductor chip and the substrate can be improved.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out in the appended claims.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a cross-sectional view showing a conventional semiconductor package;

FIG. 2 is a cross-sectional view showing a conventional semiconductor substrate;

FIG. 3 is a cross-sectional view showing an embodiment of a substrate structure according to the present invention;

FIG. 4 is a view showing a manufacturing step for the semiconductor substrate according to the present invention;

FIG. 5 is a plan view showing an embodiment of a substrate structure according to the present invention;

FIG. 6 is a cross-sectional view showing an embodiment of the substrate structure according to the present invention;

FIG. 7 is a cross-sectional view showing an embodiment of a semiconductor package according to the present invention;

FIG. 8 is a cross-sectional view showing another embodiment of a semiconductor package according to the present invention;

FIG. 9 is a perspective view showing an embodiment of a semiconductor package according to the present invention;

FIG. 10 is a perspective view showing an external connection terminal surface of a semiconductor package according to the present invention;

FIG. 11 is a perspective view showing a card type module according to the present invention;

FIG. 12 is a view illustrating a data memory device in which a card type module according to the present invention is attached to a card slot; and

FIG. 13 is a view showing a state in which a card type module is installed on a adapter card for the data memory device shown in FIG. 12.

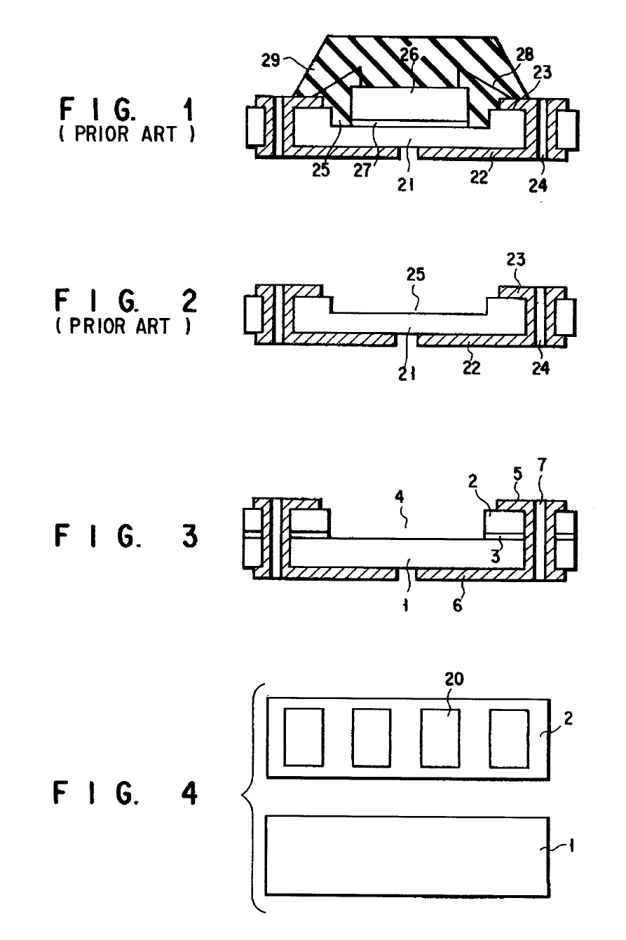

### DETAILED DESCRIPTION OF THE INVENTION

In the following, embodiments of the present invention will be explained with reference to the drawings.

FIG. 3 shows a cross-section of a substrate structure according to the present invention. FIG. 4 is a view illustrating a manufacturing step for a substrate structure according to the present invention.

As shown in FIG. 4, holes 20 are formed with use of a metal mold or the like, in a flat substrate 2 on which a wiring pattern is not yet formed. This substrate 2 and a flat substrate 1 on which a wiring pattern is not formed are adhered on each other by means of adhesion material 3 as shown in FIG. 3.

A concave portion 4 where a semiconductor chip is to be installed is thus formed.

Thereafter, through-holes 7 are formed so as to penetrate through the substrates 1 and 2, and a copper wiring pattern is formed. Gold plating processing is then performed, to form wires, a chip connection terminal 5, an external terminal 6, and the likes.

At the bottom of the concave portion 4 in this substrate structure, the surface of the substrate 1 is directly exposed.

Since the substrates 1 and 2 are thus adhered on each other, processing precision of the bottom surface of the concave portion is substantially 0 μm according to the present embodiment, in comparison with processing precision of a bottom surface of a conventional substrate which is ±30 μm, in relation to a design value. Thus, the unevenness of the concave portion 4 is reduced so that the adhesion between the semiconductor chip and the substrate 1 is excellent and the outlook of the substrate is improved.

As shown in FIG. 5, a wiring pattern 31 is provided so as to extend from each of chip connection terminals 5 and to be connected through through-holes to external connection terminals 6 provided on the back surface of the substrate 1.

Reference numeral 32 indicates a boundary enclosed by resin. Further, a broken line denoted by reference numeral 33 indicates a cutting line along which a semiconductor package enclosed with resin is to be cut out after the resin enclosing process.

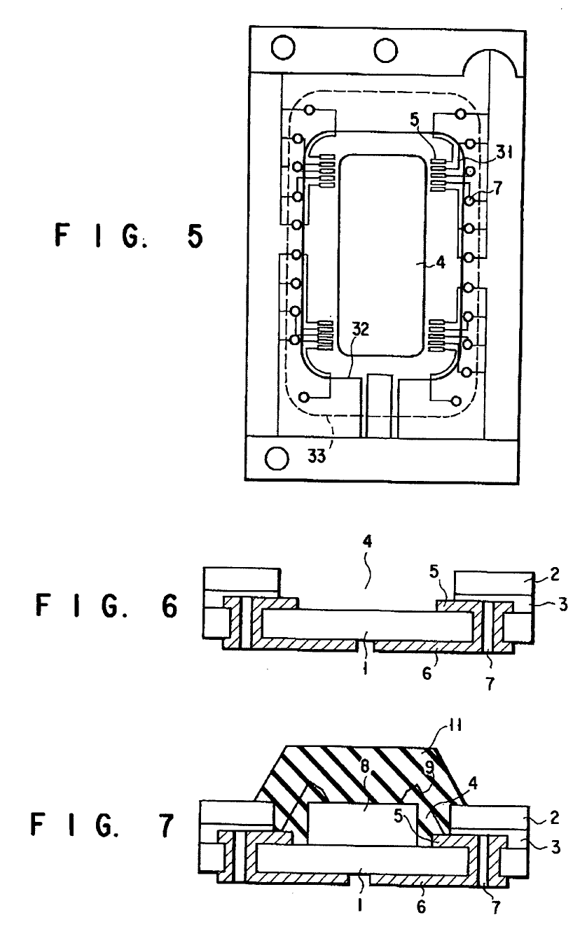

FIG. 6 shows a second embodiment of the substrate structure according to the present invention.

Through holes 7 penetrating through a flat substrate 1 are formed. In the next, copper patterns are formed on both surfaces of the substrate 1 and are subjected to gold plating processing, thereby to form a wiring pattern, chip connection terminals 5, and a flat external connection terminals 6.

Holes are provided in a substrate 2 with use of a metal mold or the like, and the substrate 1 both surfaces of which are plated is adhered on the substrate 2 having holes, by means of adhesion material 3. As a result of this, a substrate structure having a concave portion 4 where a semiconductor chip is installed is completed.

In the substrate structure of this embodiment, since the surface of the substrate 1 is directly exposed at the bottom surface of the concave portion 4, unevenness is reduced so that excellent adhering is realized between the semiconductor chip and the substrate 1.

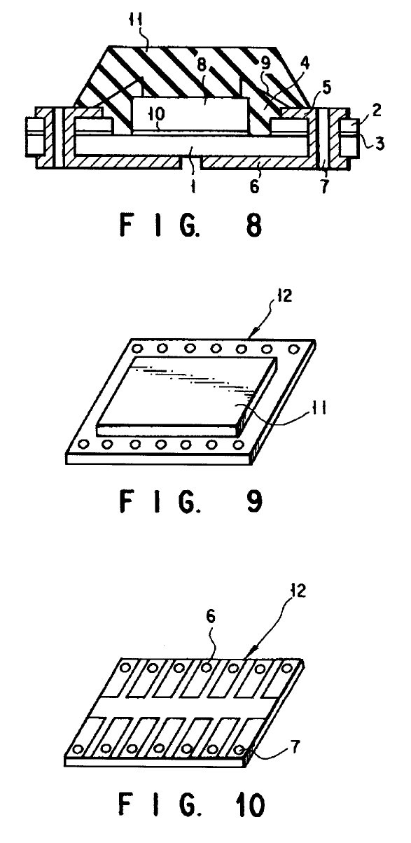

FIG. 7 shows a cross-section of a semiconductor package in which a semiconductor chip 8 is mounted on the substrate structure shown in FIG. 6 according to the present invention.

The semiconductor chip 8 shown in FIG. 7 is contained and adhered within an opening portion 4 of a second substrate 2, on the surface of the first substrate 1. Chip connection terminals 5 on the substrate 1 and bonding pads (not shown) of the semiconductor chip 1 are connected to each other, for example, by gold wires 9. Enclosing with resin 11 is performed so as to cover the semiconductor chip 8 on the first and second substrates 1 and 2.

FIG. 8 shows a cross-section of a semiconductor package in which a semiconductor chip 8 is mounted on the substrate structure shown in FIG. 3 according to the present invention.

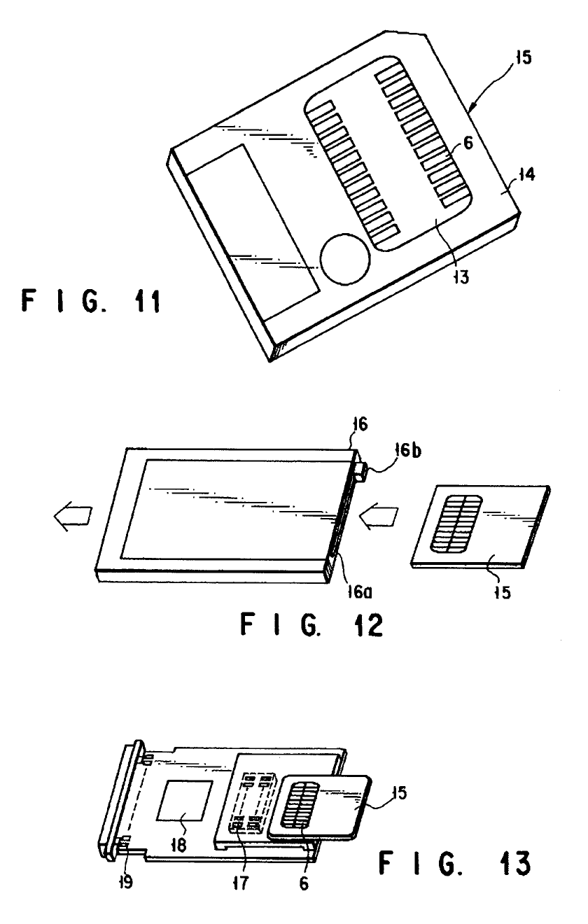

FIG. 9 is a perspective view showing the enclosed surface after resin-enclosing is performed on the semiconductor package. FIG. 10 is a perspective view showing the surface of the semiconductor package in the side of external connection terminals.

The semiconductor chip 8 shown in FIG. 8 is fixed to a concave portion 4 of the substrate 2 by adhesion material 10, and chip connection terminals 5 on the substrate are connected to bonding pads (not shown) of the semiconductor chip 8, for example, by gold wires 9. One surface of the substrate 1 is enclosed with resin 11 such that the semiconductor chip 8 is covered thereby.

External connection terminals 6 are provided on the other surface of the substrate 1 where resin-enclosing is not provided.

The external connection terminals 6 are electrically connected to chip connection terminals 5 by wires passing through through-holes 7 penetrating both the substrates 1 and 2. Note that bumps may be used in place of gold wires 9 to connect the chip connection terminals on the substrate to the semiconductor chip by flip-chip connection.

At least, a non-volatile memory is used as the semiconductor chip 8.

For example, a flash type memory of NAND type is used as the non-volatile memory.

This semiconductor package is used in, for example, a card type module 15 as shown in FIG. 11. A base card 14 thereof is made of resin and has a size of 37 mm×45 mm×0.76 mm (height×width×thickness), and a concave portion is provided for embedding a semiconductor package.

The semiconductor package 13 is embedded such that the surfaces of the external terminals 6 are situated in a plane substantially equal to the surface of the base card 14, with the resin-enclosing surface of the package 13 kept facing the concave portion.

The card type module 15 described above is used in an IC memory card or the like.

FIG. 12 shows a data memory device used for attaching the card type module 15 to, for example, a PCMCIA card slot or the like.

An adapter card 16 has a card type shape. This adapter card 16 has an insertion opening 16a to allow the card type module 15 to be attached, and comprises a connector 19 standardized to be attached to a PCMCIA slot of a personal computer.

The adapter card 16 is internally provided with a connector 17 to be brought into contact with the external connection terminals 6 of the card type module 15, as well as an interface circuit 18 which achieves an interface function between the card type module 15 and a personal computer or the like.

The connectors 17 and 19 and the interface circuit 18 are constructed in an integrated structure, for example, as shown in FIG. 13, and form a card-like shape.

When the card type module 15 is attached to the adapter card 16, these module and card function as a data memory device. Although not shown in figures, the adapter card may be a different type other than a card type which is attached to a PCMCIA card slot, and the connector 17 to make contact with external connection terminals 6 of a card type module 15 and the interface circuit 18 may be comprised in a main body of a personal computer, camera, or the like.

In addition, the adapter card may be internally provided with a drive circuit or the like for controlling the card type module 15 by electric signals.

The adapter card has a guide mechanism (not shown) for guiding a card-shaped module while the module is being inserted into or removed from the adapter card. The adapter card has a push button 16b as shown in FIG. 12. The adapter card may incorporate a mechanism (not shown) designed to push a card-shaped module out of the adapter card when the push button is depressed.

As described above, the IC memory card comprises a memory section and a CPU section. The memory section includes at least a nonvolatile memory. The CPU section, which drives the memory, is provided in, for example, a personal computer if the adapter card or the adapter is provided in the personal computer. The memory section can be easily replaced by another, by replacing the IC memory card with another.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A substrate for a semiconductor device comprising:
a flat first substrate;
a second substrate adhered on a surface of the first substrate and having an opening from which the surface of the first substrate is exposed and which contains a semiconductor chip;
a chip connection terminal provided on the second substrate and connected to the semiconductor chip;
an external connection terminal provided on a back surface of the first substrate;
a through-hole provided so as to penetrate the first and second substrates; and
a wiring pattern extending through the through-hole thereby connecting the chip connection terminal to the external terminal.

2. A substrate for a semiconductor device comprising:
a flat first substrate;
a chip connection terminal provided on a surface of the first substrate and connected to a semiconductor chip;
an external connection terminal provided on a back surface of the first substrate;
a through-hole provided so as to penetrate the first substrate;
a wiring pattern extending through the through-hole thereby connecting the chip connection terminal to the external terminal; and
a second substrate adhered on the surface of the first substrate and having an opening from which the surface of the first substrate and the chip connection terminal are exposed and which contains the semiconductor chip.

3. A semiconductor device comprising:
a flat first substrate;
a semiconductor chip provided on the first substrate;
a second substrate adhered on a surface of the first substrate and having an opening from which the surface of the first substrate is exposed and which contains the semiconductor chip;
a chip connection terminal provided on the second substrate and connected to the semiconductor chip;
an external connection terminal provided on a back surface of the first substrate;
a through-hole provided so as to penetrate the first and second substrates;
a wiring pattern extending through the through-hole thereby connecting the chip connection terminal to the external terminal; and
resin for sealing the semiconductor chip on the first and second substrates.

4. A semiconductor device:
a flat first substrate;
a semiconductor chip provided on the first substrate;
a chip connection terminal provided on a surface of the first substrate and connected to the semiconductor chip;
an external connection terminal provided on a back surface of the first substrate;
a through-hole provided so as to penetrate the first substrate;
a wiring pattern extending through the through-hole thereby connecting the chip connection terminal to the external terminal;
a second substrate adhered on the surface of the first substrate and having an opening from which the surface of the first substrate and the chip connection terminal are exposed and which contains the semiconductor chip; and
resin for sealing the semiconductor chip on the first and second substrates.

5. A card type module comprising
a base card having a concave portion, and
a semiconductor device provided in the concave portion, the semiconductor device including:
a flat first substrate;
a semiconductor chip provided on the first substrate;
a second substrate adhered on a surface of the first substrate and having an opening from which the surface of the first substrate is exposed and which contains the semiconductor chip;
a chip connection terminal provided on the second substrate and connected to the semiconductor chip,
an external connection terminal provided on a back surface of the first substrate;
a through-hole provided so as to penetrate the first and second substrates;
a wiring pattern extending through the through-hole thereby connecting the chip connection terminal to the external terminal; and
resin for sealing the semiconductor chip on the first and second substrates.

6. A card type module comprising
a base card having a concave portion, and
a semiconductor device provided in the concave portion of the base card, the semiconductor device including:
a flat first substrate;
a semiconductor chip provided on the first substrate;
a chip connection terminal provided on a surface of the first substrate and connected to the semiconductor chip,
an external connection terminal provided on a back surface of the first substrate;
a through-hole provided so as to penetrate the first substrate;
a wiring pattern extending through the through-hole thereby connecting the chip connection terminal to the external terminal;
a second substrate adhered on the surface of the first substrate and having an opening from which the surface of the first substrate and the chip connection terminal are exposed and which contains the semiconductor chip; and
resin for sealing the semiconductor chip on the first and second substrates.

7. A data memory device comprising
a card type module including a base card having a concave portion and a semiconductor device provided in the concave portion,
connector means consisting of a first connector connected to an external terminal of the card type module and a second connector connected to devices, and
an interface control circuit connected to the first and second connector, the semiconductor device including:
a flat first substrate;
a semiconductor chip provided on the first substrate;
a second substrate adhered on a surface of the first substrate and having an opening from which the surface of the first substrate is exposed and which contains the semiconductor chip;
a chip connection terminal provided on the second substrate and connected to the semiconductor chip;
an external connection terminal provided on a back surface of the first substrate;
a through-hole provided so as to penetrate the first and second substrates;
a wiring pattern extending through the through-hole thereby connecting the chip connection terminal to the external terminal; and
resin for sealing the semiconductor chip on the first and second substrates.

8. A data memory device comprising
a card type module including a base card having a concave portion and a semiconductor device provided in the concave portion of the base card,
connector means consisting of a first connector connected to an external connection terminal of the card type module and a second connector connected to devices, and
an interface control circuit connected to the first and second connectors, the semiconductor device including:
a flat first substrate;
a semiconductor chip provided on the first substrate;
a chip connection terminal provided on a surface of the first substrate and connected to the semiconductor chip,
an external connection terminal provided on a back surface of the first substrate;
a through-hole provided so as to penetrate the first substrate;
a wiring pattern extending through the through-hole thereby connecting the chip connection terminal to the external terminal;
a second substrate adhered on the surface of the first substrate and having an opening from which the surface of the first substrate and the chip connection terminal are exposed and which contains the semiconductor chip; and
resin for sealing the semiconductor chip on the first and second substrates.

9. A data memory device according to claim 7, wherein the first connector, the second connector, and the interface control circuit are integrated to form an adapter card having a card-like shape.

10. A data memory device according to claim 8, wherein the first connector, the second connector, and the interface control circuit are integrated to form an adapter card having a card-like shape.

11. A data memory device according to claim 10, wherein the card type module is attached to the adapter card.
